(19) United States
(12) Patent Application Publication
(10) Pub. No.: US 2026/0346598 A1
(43) Pub. Date: Nov. 5, 2026

(54) SCREEN PRINTING MACHINE

(71) Applicant: FUJI CORPORATION, Chiryu (JP)

(72) Inventor: Takeshi KONDO, Chiryu-shi (JP)

(73) Assignee: FUJI CORPORATION, Chiryu (JP)

(21) Appl. No.: 19/126,897

(22) PCT Filed: Nov. 24, 2022
(86) PCT No.: PCT/JP2022/043299

§ 371 Date: May 2, 2025

(51) Int. Cl. B41F 15/12; B41F 15/08; B41F 15/22; B41F 15/36; B41F 15/44; B41F 33/00

(52) U.S. Cl. CPC B41F 15/12; B41F 15/0818; B41F 15/22; B41F 15/36; B41F 15/44; B41F 33/0009

(57) ABSTRACT

A screen printing machine prints viscous fluid on a board using a mask on which a printing pattern including a through hole is formed. The screen printing machine includes: a board holding device configured to hold the board; a mask holding device configured to hold an end portion of the mask along an outer periphery of the mask at a position above the board held by the board holding device; an air nozzle configured to discharge air toward a target point on an upper surface of the mask held at the position above the board; and a displacement amount measurement device configured to measure a displacement amount of one or multiple measurement target points, which are points on the upper surface before and after the discharge of the air and correspond to the target point, in an up-down direction when the air is discharged from the air nozzle toward the target point.

### TECHNICAL FIELD

A technique disclosed in the present description relates to a screen printing machine.

### BACKGROUND ART

A screen printing machine that fills a through hole of a mask with a viscous fluid in a state of holding the mask above a board. In the screen printing machine, when a gap is formed between the mask and the board when the through hole is filled with the viscous fluid, the viscous fluid may enter the gap. A screen printing machine of Patent Literature 1 presses a shaft of an actuator against an upper surface of a mask from above the mask. Accordingly, the mask is displaced downward toward a board according to a size of the gap formed between the mask and the board. The screen printing machine measures a distance between the mask and the board based on a displacement amount of the shaft of the actuator (that is, the mask).

### CITATION LIST

### Patent Literature

Patent Literature 1: JPH04-100849U

### BRIEF SUMMARY

### Technical Problem

The above-described screen printing machine presses the shaft of the actuator against the upper surface of the mask in order to measure the distance between the mask and the board. Therefore, the shaft may damage the upper surface of the mask. The present description provides a technique with which it is possible to reduce damage to an upper surface of a mask when a distance between the mask and a board is measured as compared with the related art.

### Solution to Problem

A screen printing machine disclosed in the present description prints viscous fluid on a board using a mask on which a printing pattern including a through hole is formed. The screen printing machine includes a board holding device configured to hold the board, a mask holding device configured to hold an end portion of the mask along an outer periphery of the mask at a position above the board held by the board holding device, an air nozzle configured to discharge air toward a target point on an upper surface of the mask held at the position above the board, and a displacement amount measurement device configured to measure a displacement amount of one or multiple measurement target points, which are points on the upper surface before and after the discharge of the air and correspond to the target point, in an up-down direction when the air is discharged from the air nozzle toward the target point.

With the above-described screen printing machine, the mask is displaced by the air discharged from the air nozzle without directly contacting the upper surface of the mask. Accordingly, it is possible to measure the displacement amount of the measurement target point on the upper surface of the mask in the up-down direction in a non-contact manner. The above-described screen printing machine is capable of reducing damage to the upper surface of the mask when a distance between the mask and the board is measured.

### BRIEF DESCRIPTION OF DRAWINGS

FIG. 1 is a side view of a screen printing machine according to a first example.

FIG. 2 is an enlarged view of a range of a broken line II in FIG. 1.

FIG. 3 is a plan view of a mask disposed in the screen printing machine according to the first example.

FIG. 4 is a configuration diagram of a control device of the screen printing machine according to the first example.

FIG. 5 is a flowchart of a board printing process executed by the control device according to the first example.

FIG. 6 is a flowchart of a board printing process executed by a control device according to a second example.

### DESCRIPTION OF EMBODIMENTS

Main features of an example described below are listed. Technical elements described below are independent technical elements, respectively, exhibit technical usefulness alone or in various combinations, and are not limited to the combinations disclosed in the claims as originally filed.

(Feature 1) In the above-described screen printing machine, the one or multiple measurement target points may include the target point.

When air is discharged from a nozzle toward the target point, the displacement in an up-down direction is likely to be large at the target point than at a point around the target point. With such a configuration, it is possible to easily measure the displacement in the up-down direction as compared with a configuration in which a displacement amount of the point around the target point in the up-down direction is measured.

(Feature 2) The above-described screen printing machine may further include a board lifting device configured to lift the board holding device when the viscous fluid is printed on the board, and a lifting amount determination section configured to determine a lifting amount of the board holding device. In this case, the lifting amount determination section may be configured to determine the lifting amount based on the displacement amount of the one or multiple measurement target points measured by the displacement amount measurement device.

With such a configuration, it is possible to bring the board close to a mask based on the displacement amount of the one or multiple measurement target points. Therefore, it is possible to reduce a distance between the board and the mask when the viscous fluid is printed on the board.

(Feature 3) The above-described screen printing machine may further include a discharge amount determination section configured to determine a discharge amount of the air discharged by the air nozzle. In this case, the target point may include a first target point and a second target point different from the first target point. The discharge amount determination section may be configured to determine the discharge amount of the air with respect to the second target point to be a second discharge amount different from a first discharge amount of the air with respect to the first target point. The displacement amount measurement device may be configured to measure a displacement amount of a first measurement target point, which corresponds to the first target point, in the up-down direction and measure a displacement amount of a second measurement target point, which corresponds to the second target point, in the up-down direction.

With such a configuration, it is possible to change the discharge amount of the air according to a position of the target point. Accordingly, it is possible to determine the discharge amount of the air suitable for the position of the target point.

(Feature 4) The above-described screen printing machine may further include an opening area determination section configured to determine an opening area of a discharge port of the air nozzle. In this case, the target point may include a first target point and a second target point different from the first target point. The opening area determination section may be configured to determine the opening area of the discharge port with respect to the second target point to be a second opening area different from a first opening area of the discharge port with respect to the first target point. The displacement amount measurement device may be configured to measure a displacement amount of a first measurement target point, which corresponds to the first target point, in the up-down direction and measure a displacement amount of a second measurement target point, which corresponds to the second target point, in the up-down direction.

With such a configuration, it is possible to change the opening area according to the position of the target point. Accordingly, it is possible to determine the opening area suitable for the position of the target point.

(Feature 5) The above-described screen printing machine may further include an operation control section configured to control an operation of the board holding device, in which the board holding device may include a clamp configured to grip an end portion of the board. In this case, the operation control section may be configured to, when the displacement amount of the measurement target point measured by the displacement amount measurement device exceeds a predetermined threshold amount, cause the clamp to release the end portion of the board and then cause the clamp to grip the end portion of the board again.

When the clamp grips the end portion of the board, the board may bend. In this case, the distance between the mask and the board is likely to be large. As a result, the displacement amount of the measurement target point in the up-down direction increases. With such a configuration, when the displacement amount exceeds a predetermined threshold, the clamp is caused to release the end portion of the board and to grip the end portion of the board again. Accordingly, the bending of the board can be eliminated.

(Feature 6) The above-described screen printing machine may further include a squeegee configured to fill the through hole of the mask with the viscous fluid, and a squeegee operation determination section configured to determine a force with which the squeegee is pressed against the upper surface of the mask, and a speed at which the squeegee is moved along the upper surface of the mask. In this case, the squeegee operation determination section may be configured to determine at least one of the force and the speed based on the displacement amount of the measurement target point measured by the displacement amount measurement device.

With such a configuration, an operation (that is, at least one of the force and the speed) of the squeegee is determined according to the displacement amount. Accordingly, the screen printing machine can perform printing suitable for the distance between the mask and the board.

### First Example

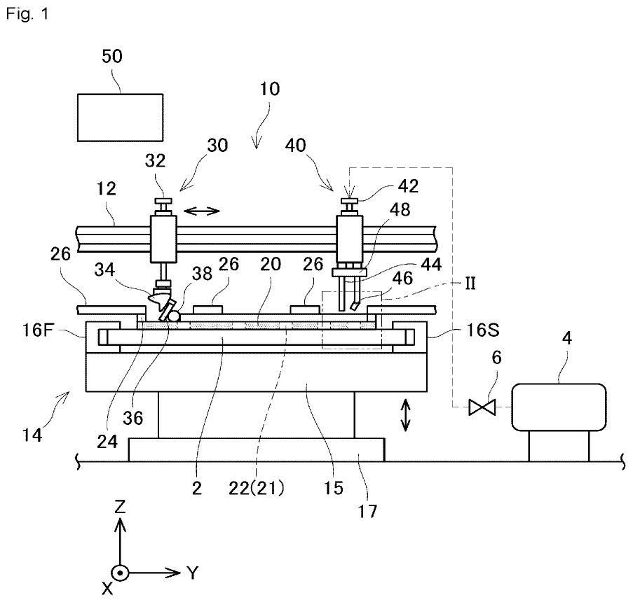

A configuration of screen printing machine 10 (hereinafter, referred to as printing machine 10) according to a first example will be described with reference to FIGS. 1 to 3. Printing machine 10 is a device that prints cream solder 38, which is viscous fluid, on circuit board 2 (hereinafter, referred to as board 2), which is an object on which printing is performed, using mask 20, and conveys printed board 2 to an electronic component mounting device, which is a post-process. Hereinafter, a −Y direction in the drawings is expressed as a front side. A +Y direction is expressed as a rear side, a +Z direction is expressed as an upper side, and a −Z direction is expressed as a lower side.

FIG. 1 is a side view of printing machine 10. Printing machine 10 includes squeegee unit 30, unit driving device 12, mask holding device 24, board holding device 14, gap measurement unit 40, control device 50, high-pressure tank 4, and adjustment valve 6 in a box-shaped housing. In FIG. 1, the housing of printing machine 10 is illustrated in a see-through manner, but actually, the housing is formed of six plate materials and partitions an inside of printing machine 10.

Squeegee unit 30 includes squeegee 36, angle adjustment device 34, and lifting and lowering device 32. Squeegee 36 is a flat plate-shaped member and has a rectangular shape extending in an X-axis direction. Squeegee 36 of the present example is a metal squeegee made of metal, but in a modification, for example, may be a urethane squeegee. Angle adjustment device 34 adjusts a posture of squeegee 36 with respect to board 2 (an angle formed by an upper surface of board 2 and squeegee 36). Lifting and lowering device 32 moves squeegee 36 in the up-down direction. Further, lifting and lowering device 32 lifts and lowers squeegee 36 in the up-down direction with respect to board 2 to adjust a pressure for pressing squeegee 36 against mask 20 (hereinafter, referred to as a printing pressure).

Board holding device 14 includes pair of clamps 16F and 16S. Pair of clamps 16F and 16S grip board 2 from the front and rear. Thus, board 2 is fixed to board holding device 14. Board lifting device 15 and board conveyance device 17 are disposed below board holding device 14. Board lifting device 15 has a servo motor (not shown). Board lifting device 15 operates the servo motor to lift and lower board holding device 14. Similarly, board conveyance device 17 has a servo motor (not shown), and operates the servo motor to convey board 2 before printing to board holding device 14 and convey board 2 on which printing has been completed from board holding device 14 in a +X direction (that is, a direction closer to the viewer in the drawing of FIG. 1).

Unit driving device 12 moves squeegee unit 30 along a pair of guide rails in a front-rear direction of printing machine 10 (that is, a left-right direction in the drawing of FIG. 1). A detailed structure in which unit driving device 12 moves squeegee unit 30 in the front-rear direction is known, and thus a description thereof will be omitted here.

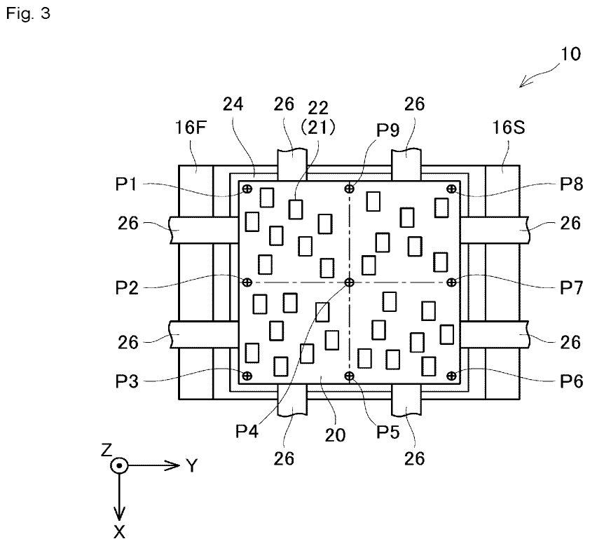

In particular, as shown in FIG. 3, mask holding device 24 includes frame body disposed along an outer periphery of mask 20. The frame body of mask holding device 24 holds end portions of mask 20. Accordingly, it is possible to reduce the displacement of mask 20 when through hole 22 of mask 20 is filled with cream solder 38 by squeegee unit 30. Mask holding device 24 is provided with multiple holding mechanisms 26. Mask holding device 24 holding the end portions of mask 20 is held at a position above board 2 by multiple holding mechanisms 26.

Multiple through holes 22 are formed in mask 20. Multiple through holes 22 are arranged according to printing pattern 21. When cream solder 38 is pressed against the upper surface of mask 20 by squeegee 36, cream solder 38 passes through multiple through holes 22 (that is, printing pattern 21) and adheres to board 2. Accordingly, cream solder 38 is printed on the upper surface of board 2 according to printing pattern 21.

Gap measurement unit 40 is a unit for measuring a distance (gap) between mask 20 and the upper surface of board 2 when cream solder 38 is printed on board 2. Gap measurement unit 40 includes air nozzle 44 (hereinafter, referred to as nozzle 44), displacement sensor 46, lifting and lowering device 42, and driving device 48. Nozzle 44 is connected to high-pressure tank 4 via adjustment valve 6. Compressed air is stored in high-pressure tank 4. When adjustment valve 6 is opened, the air in high-pressure tank 4 is discharged from nozzle 44 toward mask 20. A discharge amount of air discharged from nozzle 44 toward mask 20 is changed according to an opening degree of adjustment valve 6.

Displacement sensor 46 is a so-called optical sensor. Displacement sensor 46 includes a light projecting section and a light receiving section therein. Displacement sensor 46 emits laser light from the light projecting section toward an object to be measured. The irradiated light is reflected by the object to be measured, and the reflected light is incident on the light receiving section. Displacement sensor 46 detects the displacement of an object to be measured based on a change in a position of the light incident on the light receiving section. In a modification, displacement sensor 46 may be, for example, an ultrasonic sensor.

Lifting and lowering device 42 moves nozzle 44 and displacement sensor 46 in the up-down direction. Driving device 48 moves nozzle 44 and displacement sensor 46 in an X direction. Gap measurement unit 40 is movable in the front-rear direction of printing machine 10 (Y direction) by unit driving device 12. That is, gap measurement unit 40 can move nozzle 44 and displacement sensor 46 along the upper surface of mask 20.

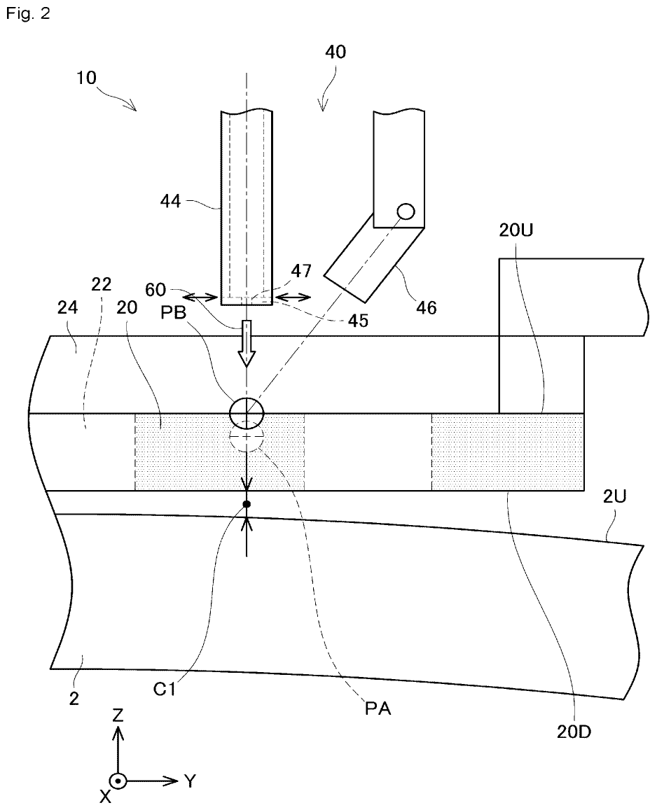

Nozzle 44 and displacement sensor 46 of gap measurement unit 40 will be described with reference to FIG. 2. Nozzle 44 has a cylindrical shape extending in the up-down direction. Opening 47 and opening adjustment section 45 are provided at a lower end of nozzle 44. Opening adjustment section 45 is a mechanism for changing an area of opening 47, and includes a wall that defines opening 47 of nozzle 44. By the wall of opening adjustment section 45 moving toward the center of nozzle 44, the area of opening 47 of nozzle 44 decreases. By the wall of opening adjustment section 45 moving in a direction away from the center of nozzle 44, the area of opening 47 increases.

As described above, mask 20 is held by mask holding device 24 at a position above board 2. Further, board 2 is disposed below mask 20 in a state where the end portions thereof are held by pair of clamps 16F and 16S of board holding device 14. Here, since mask 20 has a thin film shape of, for example, 1 mm or less, mask 20 can be partially displaced in the up-down direction. Further, since board 2 also has a relatively thin flat plate shape, when the end portions of board 2 are gripped by clamps 16F and 16S, board 2 may be deformed, for example, such that a central portion is directed upward. As a result, as shown in FIG. 2, a gap having length C1 that changes depending on a location may be formed between lower surface 20D of mask 20 and upper surface 2U of board 2.

When a large gap is formed between lower surface 20D of mask 20 and upper surface 2U of board 2, cream solder 38 enters the gap when through hole 22 is filled with cream solder 38. As a result, a printing defect in which cream solder 38 is printed at an unintended position on board 2 may occur.

Gap measurement unit 40 measures a distance between lower surface 20D of mask 20 and upper surface 2U of board 2 before printing machine 10 executes printing, that is, before squeegee 36 moves rearward. Specifically, gap measurement unit 40 discharges air 60 toward target point PB on upper surface 20U of mask 20 by nozzle 44. When there is a gap between lower surface 20D of mask 20 and upper surface 2U of board 2, mask 20 is displaced downward by length C1 of the gap, and lower surface 20D of mask 20 comes into contact with upper surface 2U of board 2. That is, a displacement amount of mask 20 is length C1 of the gap. Displacement sensor 46 measures the displacement between target point PB before air 60 is discharged and target point PA after air 60 is discharged. Accordingly, gap measurement unit 40 can measure length C1 of the gap. Gap measurement unit 40 transmits measured length C1 of the gap to control device 50.

For example, as shown in FIG. 3, gap measurement unit 40 of the present example measures a length of the gap at target points P1 to P9. Target point P1, target point P3, target point P6, and target point P8 are arranged at four corners of mask 20. Target point P4 is disposed at the center of mask 20. Target point P2, target point P5, target point P7, and target point P9 are disposed at the centers of sides of mask 20.

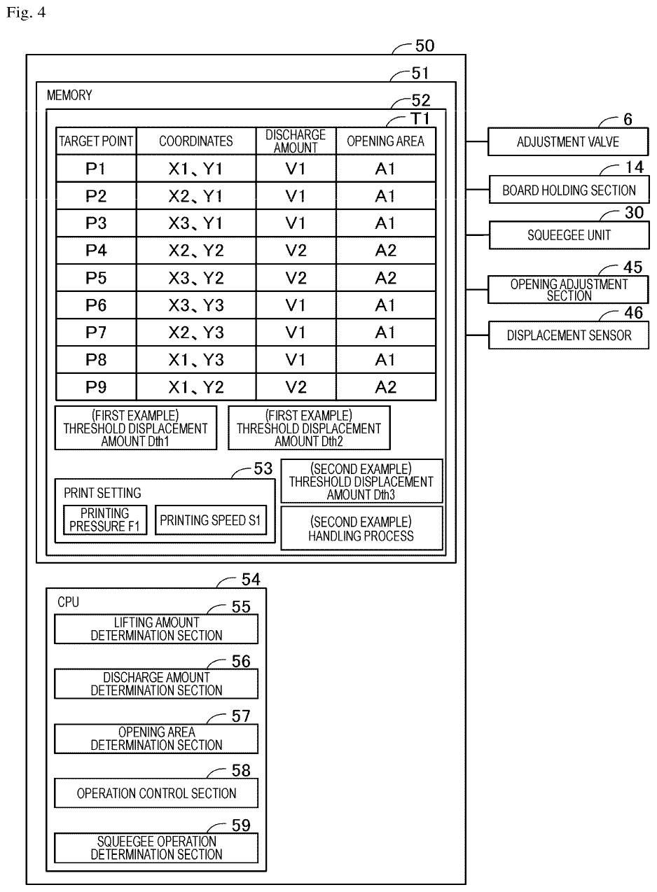

A configuration of control device 50 will be described with reference to FIG. 4. Control device 50 is configured with a computer including memory 51 and CPU 54. Control device 50 is communicably connected to devices 6 to 45 of printing machine 10.

Memory 51 includes a storage medium such as an HDD. Memory 51 stores printing program 52. Printing program 52 is a program for printing cream solder 38 on board 2 using mask 20. Printing program 52 includes target point table T1, threshold displacement amounts Dth1 and Dth2, and print setting 53.

Target point table T1 stores coordinates of each of target points P1 to P9, the discharge amount, and the opening area in association with each other. Target point table T1 is a table for determining the discharge amount of air 60 at each of target points P1 to P9 and the opening area of nozzle 44. Target point table T1 is stored in advance in printing program 52, but a worker may change, add, or delete the coordinates of the target point based on an actual printing result. Further, the worker may change the discharge amount and change the opening area.

In target point table T1 of the present example, discharge amount V1 is set for target points P1 to P3 and P6 to P8. Meanwhile, discharge amount V2 is set at target points P4, P5, and P9. As shown in FIG. 3, target points P4, P5, and P9 are positioned at the center of board 2 in the front-rear direction (that is, a left-right direction in the drawing of FIG. 3). As described above, since the end portions of board 2 in the front-rear direction are gripped by pair of clamps 16F and 16S, the central portion in the front-rear direction is likely to be displaced upward. Therefore, at target points P4, P5, and P9, the distance between upper surface 2U of board 2 and lower surface 20D of mask 20 (that is, length C1 of the gap) is likely to be small. Meanwhile, at target points P1 to P3 and P6 to P8, length C1 of the gap is likely to be large as compared with target points P4, P5, and P9. Therefore, discharge amount V1 is set to be large as compared with discharge amount V2. Accordingly, it is possible to sufficiently displace mask 20 until lower surface 20D of mask 20 comes into contact with upper surface 2U of board 2 by air 60 having discharge amount V1 larger than discharge amount V2 at the end portions of board 2, in which length C1 of the gap is large, in the front-rear direction. As a result, displacement sensor 46 can accurately measure length C1 of the gap. That is, printing machine 10 can accurately measure gap C1 by changing discharge amounts V1 and V2 according to the positions of target points P1 to P9.

Similarly, in target point table T1 of the present example, opening area A1 is set for target points P1 to P3 and P6 to P8. Meanwhile, opening area A2 is set for target points P4, P5, and P9. Opening area A1 is set to be larger than opening area A2. Accordingly, it is possible to sufficiently displace mask 20 until lower surface 20D of mask 20 comes into contact with upper surface 2U of board 2 by air 60 discharged through opening area A1 larger than opening area A2 at the end portions of board 2, in which length C1 of the gap is large, in the front-rear direction. As a result, the distance between upper surface 2U of board 2 and lower surface 20D of mask 20 can be accurately measured. That is, printing machine 10 can accurately measure length C1 of the gap by further changing opening areas A1 and A2 according to the positions of target points P1 to P9.

Threshold displacement amount Dth1 is a threshold for control device 50 to determine whether to reset pair of clamps 16F and 16S in a board printing process described later. Threshold displacement amount Dth2 is a threshold for control device 50 to determine whether to change print setting 53 in the board printing process. Each of threshold displacement amount Dth1 and DTh2 is stored in advance in printing program 52, but may be changed by the worker.

Print setting 53 includes printing pressure F1 and printing speed S1. These are values stored in advance in printing program 52. Control device 50 is configured to adjust the printing pressure with lifting and lowering device 32 of squeegee unit 30. The printing speed is a speed at which squeegee unit 30 advances rearward while filling through holes 22 of mask 20 with cream solder 38. Control device 50 is configured to adjust the printing speed with unit driving device 12.

CPU 54 executes various processes according to printing program 52. As a result, CPU 54 functions as lifting amount determination section 55, discharge amount determination section 56, opening area determination section 57, operation control section 58, and squeegee operation determination section 59.

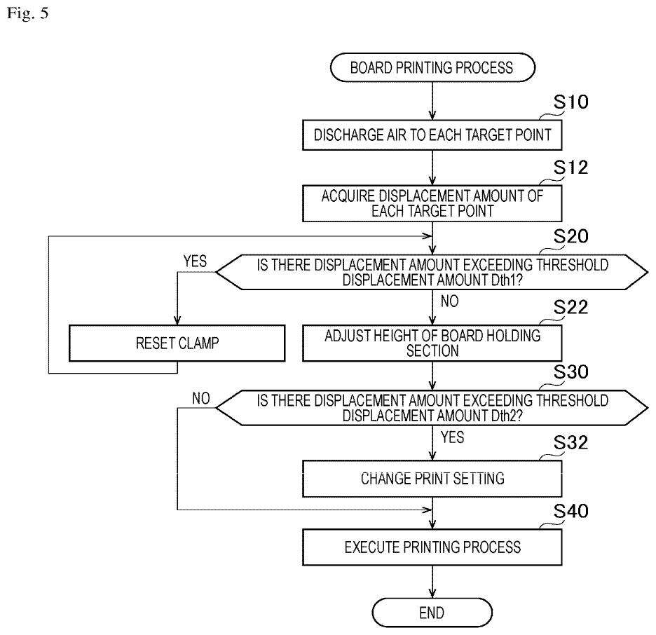

The board printing process executed by CPU 54 of control device 50 of printing machine 10 will be described with reference to FIG. 5. After mask 20 is held by mask holding device 24 and board 2 is held by board holding device 14, the board printing process is started in response to a printing start instruction from the worker.

In S10, CPU 54 moves nozzle 44 and displacement sensor 46 in an order of target points P1 to P9 based on target point table T1. When nozzle 44 and displacement sensor 46 are moved to each of target points P1 to P9, CPU 54 causes nozzle 44 to discharge air 60 toward each of target points P1 to P9. In this case, as described above, CPU 54 changes the discharge amount to discharge amount V1 or V2 and the opening area to opening area A1 or A2 according to target points P1 to P9 based on target point table T1.

In S12, CPU 54 acquires the displacement amount of each of target points P1 to P9 before and after the discharge of air 60 from displacement sensor 46.

In S20, CPU 54 compares the displacement amounts acquired from displacement sensor 46 with threshold displacement amount Dth1. When a displacement amount exceeding threshold displacement amount Dth1 is not included in the displacement amounts (S20: NO), CPU 54 proceeds to S22, and when a displacement amount exceeding threshold displacement amount Dth1 is included in the displacement amounts (S20: YES), CPU 54 proceeds to S24.

In S24, CPU 54 resets pair of clamps 16F and 16S. Specifically, CPU 54 causes pair of clamps 16F and 16S to release the end portions of board 2 in the front-rear direction. Thereafter, CPU 54 causes pair of clamps 16F and 16S to grip the end portions of board 2 in the front-rear direction again. As a result, deformation of board 2 due to the gripping of pair of clamps 16F and 16S can be eliminated. As a result, it is possible to reduce length Cl of the gap described above.

In S22, CPU 54 adjusts a height of board holding device 14 according to the displacement amount of each of target points P1 to P9 acquired from displacement sensor 46 in S12. For example, CPU 54 causes board lifting device 15 to lift board holding device 14 by a maximum displacement amount among the displacement amounts acquired from displacement sensor 46 in S12. Thus, when cream solder 38 is printed on board 2, lower surface 20D of mask 20 and upper surface 2U of board 2 can be brought into contact with each other. As a result, it is possible to reduce occurrence of the printing defect described above. In a modification, CPU 54 may cause board holding device 14 to be lifted by an average value of the displacement amounts of target points P1 to P9 acquired from displacement sensor 46 in S12.

In S30, CPU 54 compares the displacement amount of each of target points Pl to P9 acquired from displacement sensor 46 with threshold displacement amount Dth2. When a displacement amount exceeding threshold displacement amount Dth2 is not included in the displacement amounts (S30: NO), CPU 54 skips S32 and proceeds to S40, and when a displacement amount exceeding threshold displacement amount Dth2 is included in the displacement amounts (S30: YES), CPU 54 proceeds to S32.

In S32, CPU 54 changes print setting 53. Specifically, CPU 54 sets the printing pressure during passage through the target point indicating a displacement amount exceeding threshold displacement amount Dth2 to be higher than initial printing pressure F1, and sets the printing speed to be lower than initial printing speed S1. Accordingly, it is possible to more strongly press mask 20 against board 2 by squeegee 36 at the target point indicating the displacement amount exceeding threshold displacement amount Dth2. As a result, it is possible to reduce occurrence of the printing defect. In a modification, print setting 53 need only include at least one of printing pressure Fl and printing speed S1. In this case, CPU 54 may change at least one of printing pressure F1 and printing speed S1 in S32.

In S40, CPU 54 executes printing by moving squeegee unit 30 rearward based on print setting 53. Thus, through hole 22 of mask 20 is filled with cream solder 38, and cream solder 38 is printed on board 2.

With printing machine 10 of the present example, it is possible to measure the displacement amounts of target points P1 to P9 in the up-down direction by air 60 discharged from nozzle 44 without directly contacting upper surface 20U of mask 20. Therefore, printing machine 10 can reduce damage to upper surface 20U of mask 20 when the distance between mask 20 and board 2 is measured.

### Second Example

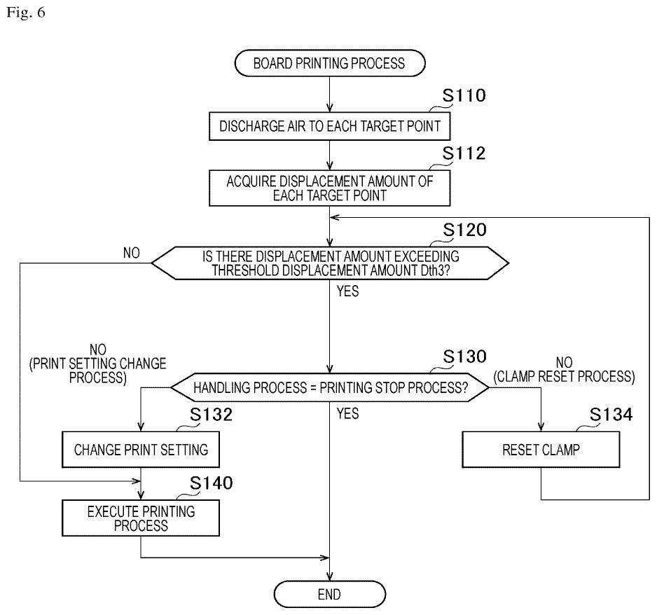

Screen printing machine 10 according to a second example will be described with reference to FIGS. 4 and 6. Screen printing machine 10 according to the second example has the same configuration as screen printing machine 10 according to the first example described above, but control device 50 of screen printing machine 10 according to the second example executes a board printing process different from that of control device 50 of the first example.

As shown in FIG. 4, printing program 52 of the second example includes one threshold displacement amount Dth3 instead of two threshold displacement amounts Dth1 and Dth2 of the first example. Further, a handling process is registered in printing program 52 of the second example. Threshold displacement amount Dth3 is a threshold for control device 50 to determine whether to execute the handling process in the board printing process shown in FIG. 6. The handling process includes a print setting change process, a clamp reset process, and a printing stop process. The print setting change process is a process of changing print setting 53 described above. The clamp reset process is a process of resetting pair of clamps 16F and 16S described above. The printing stop process is a process of stopping the board printing process. The worker selects one of the three processes before executing the board printing process. The selected process is registered in printing program 52 as the handling process.

The board printing process executed by CPU 54 of screen printing machine 10 according to the second example will be described with reference to FIG. 6. In S110 and S112, processes similar to S10 and S12 in FIG. 5 are executed. In S120, CPU 54 compares the displacement amounts acquired from displacement sensor 46 with threshold displacement amount Dth3. When a displacement amount exceeding threshold displacement amount Dth3 is not included in the displacement amounts (S120: NO), CPU 54 proceeds to S140 and executes the printing process. When a displacement amount exceeding threshold displacement amount Dth3 is included in the displacement amounts (S120: YES), CPU 54 proceeds to S130.

In S130, CPU 54 determines whether the handling process registered in printing program 52 is the printing stop process. When the handling process is the printing stop process (S130: YES), CPU 54 stops the board printing process. As a result, the worker can confirm a portion displaced beyond threshold displacement amount Dth3 and correct the board or the mask at the portion.

When the handling process registered in printing program 52 is the print setting change process (S130: NO), CPU 54 changes print setting 53 in S132 and executes the printing process (S140). In S132, the same process as S32 in FIG. 5 is executed.

When the handling process registered in printing program 52 is the clamp reset process (S130: NO), CPU 54 resets pair of clamps 16F and 16S in S134 and returns to S120.

Points to be noted regarding printing machine 10 described in the example will be described. Instead of measuring the displacement of the target point (for example, P1), displacement sensor 46 may measure, for example, displacements of four points on the same circumference around target point P when board 2 is viewed in a plan view. By measuring the displacements of the four points corresponding to target point P, length C1 of the gap around target point P can be accurately measured. Further, it is possible to measure on which side board 2 or mask 20 is inclined around target point P. In the present modification, the four points are an example of the “multiple measurement target points”.

Nozzle 44 of printing machine 10 may discharge air 60 toward only one target point P1, for example. In this case, discharge amounts V1 and V2 need not be stored in target point table T1. In the present modification, the “discharge amount determination section” may be omitted. In another modification, opening areas A1 and A2 need not be stored in target point table T1. In the present modification, the “opening area determination section” may be omitted.

Board holding device 14 need not include pair of clamps 16F and 16S. In this case, board 2 may be disposed, for example, on an upper surface of board holding device 14. In this case, CPU 54 need not execute the processes of S20 and S22. In the present modification, the “operation control section” may be omitted.

CPU 54 need not execute the processes of S30 and S32. In the present modification, the “squeegee operation determination section” can be omitted.

Instead of the discharge amounts or the opening areas, discharge pressures may be stored in target point table T1 in association with the coordinates of target points P1 to P9. In this case, for example, the discharge pressures associated with target points P1 to P3 and P6 to P8 may be set to be large as compared with the discharge pressures associated with target points P4, P5, and P9. In a further modification, in addition to the discharge amounts and the opening areas, the discharge pressures may be further stored in target point table T1 in association with the coordinates of target points P1 to P9.

In target point table T1 described above, the discharge amount and the opening area are changed according to distances between target points P1 to P9 and pair of clamps 16F and 16S. Alternatively, the discharge amount and the opening area may be changed according to, for example, the distances between target points P1 to P9 and mask holding device 24. In this case, for example, large discharge amount V1 and large opening area A1 may be set for target points P1 to P3 and P5 to P9 close to mask holding device 24 among target points P1 to P9, and small discharge amount V2 and small opening area A2 may be set for target point P4 away from mask holding device 24.

The technical elements described in the present description or the drawings exhibit technical usefulness independently or in various combinations and are not limited to the combinations described in the claims as originally filed. In addition, the technique exemplified in the present description or the drawings simultaneously achieves multiple purposes, and achieving one of the purposes itself has technical usefulness.

### REFERENCE SIGNS LIST

2: circuit board
2U, 20U: upper surface
4: high-pressure tank
6: adjustment valve
10: screen printing machine
12: unit driving device
14: board holding device
15: board lifting device
16F, 16S: clamp
17: board conveyance device
20: mask
20D: lower surface
21: printing pattern
22: through hole
24: mask holding device
26: holding mechanism
30: squeegee unit
32: lifting and lowering device
34: angle adjustment device
36: squeegee
38: cream solder
40: gap measurement unit
42: lifting and lowering device
44: air nozzle
45: opening adjustment section
46: displacement sensor
47: opening
48: driving device
50: control device
51: memory
52: printing program
53: print setting
54: CPU
55: lifting amount determination section
56: discharge amount determination section
57: opening area determination section
58: operation control section
59: squeegee operation determination section
60: air
A1, A2: opening area
C1: gap
Dth1, Dth2, Dth3: threshold displacement amount
F1: printing pressure
P1 to P9, PA, PB: target point
T1: target point table
V1, V2: discharge amount

1. A screen printing machine for printing viscous fluid on a board using a mask on which a printing pattern including a through hole is formed, the screen printing machine comprising:
a board holding device configured to hold the board;
a mask holding device configured to hold an end portion of the mask along an outer periphery of the mask at a position above the board held by the board holding device;
an air nozzle configured to discharge air toward a target point on an upper surface of the mask held at the position above the board; and
a displacement amount measurement device configured to measure a displacement amount of one or multiple measurement target points, which are points on the upper surface before and after the discharge of the air and correspond to the target point, in an up-down direction when the air is discharged from the air nozzle toward the target point.

2. The screen printing machine according to claim 1, wherein the one or multiple measurement target points include the target point.

3. The screen printing machine according to claim 1, further comprising:
a board lifting device configured to lift the board holding device when the viscous fluid is printed on the board; and
a lifting amount determination section configured to determine a lifting amount of the board holding device,
wherein the lifting amount determination section is configured to determine the lifting amount based on the displacement amount of the one or multiple measurement target points measured by the displacement amount measurement device.

4. The screen printing machine according to claim 1, further comprising:
a discharge amount determination section configured to determine a discharge amount of the air discharged by the air nozzle,
wherein the target point includes a first target point and a second target point different from the first target point,
the discharge amount determination section is configured to determine the discharge amount of the air with respect to the second target point to be a second discharge amount different from a first discharge amount of the air with respect to the first target point, and
the displacement amount measurement device is configured to measure a displacement amount of a first measurement target point, which corresponds to the first target point, in the up-down direction and measure a displacement amount of a second measurement target point, which corresponds to the second target point, in the up-down direction.

5. The screen printing machine according to claim 1, further comprising:
an opening area determination section configured to determine an opening area of a discharge port of the air nozzle,
wherein the target point includes a first target point and a second target point different from the first target point,
the opening area determination section is configured to determine the opening area of the discharge port with respect to the second target point to be a second opening area different from a first opening area of the discharge port with respect to the first target point, and
the displacement amount measurement device is configured to measure a displacement amount of a first measurement target point, which corresponds to the first target point, in the up-down direction and measure a displacement amount of a second measurement target point, which corresponds to the second target point, in the up-down direction.

6. The screen printing machine according to claim 1, further comprising:
an operation control section configured to control an operation of the board holding device,
wherein the board holding device includes a clamp configured to grip an end portion of the board, and
the operation control section is configured to, when the displacement amount of the measurement target point measured by the displacement amount measurement device exceeds a predetermined threshold amount, cause the clamp to release the end portion of the board and then cause the clamp to grip the end portion of the board again.

7. The screen printing machine according to claim 1, further comprising:
a squeegee configured to fill the through hole of the mask with the viscous fluid; and
a squeegee operation determination section configured to determine a force with which the squeegee is pressed against the upper surface of the mask, and a speed at which the squeegee is moved along the upper surface of the mask,
wherein the squeegee operation determination section is configured to determine at least one of the force and the speed based on the displacement amount of the measurement target point measured by the displacement amount measurement device.
